(19) United States
(12) Patent Application Publication
(10) Pub. No.: US 2017/0233576 A1
(43) Pub. Date: Aug. 17, 2017

(54) PHTHALOCYANINE COMPOUND USED FOR COLOR FILTER OF LCD

(71) Applicant: Dow Global Technologies LLC, Midland, MI (US)

(72) Inventors: Chao He, Shanghai (CN); Guihong Liao, Shanghai (CN); Yanping Sun, Shanghai (CN); Yang Li, Shanghai (CN); Hanfei Guo, Shanghai (CN); Yu Cai, Shanghai (CN)

(21) Appl. No.: 15/328,519

(22) PCT Filed: Jul. 28, 2014
(86) PCT No.: PCT/CN14/83165

§ 371 Date: Jan. 24, 2017

(51) Int. Cl. C09B 47/04; G02B 5/22; G03F 7/038; G03F 7/00; C09B 47/067; C08K 5/00

(52) U.S. Cl. CPC C09B 47/045; C09B 47/0675; C08K 5/0091; G03F 7/038; G03F 7/0007; G02B 5/223; G02F 1/133514

(57) ABSTRACT

A phthalocyanine compound which is suitable for forming a color filter used for a liquid crystal display device, a method for synthesis the phthalocyanine compound, a composition containing a resin and the phthalocyanine compound, an article having a polymer layer formed from the composition and a color filter formed from the composition are developed.

### FIELD OF THE INVENTION

The present invention relates to a phthalocyanine compound which is suitable for forming a color filter used for a liquid crystal display device, a method for synthesis the phthalocyanine compound, a composition containing a resin and the phthalocyanine compound, an article having a polymer layer formed from the composition and a color filter formed from the composition.

### BACKGROUND OF THE INVENTION

Liquid crystal display (LCD) currently dominates the display market because of its excellent performance and small thickness. As a key component of LCD device, translucent color filters play the critical role of generating Red/Green/Blue lights by filtering white light from a back sheet. This capacity originates from the Red/Green/Blue colorants comprised in color filter units. Each colorant possesses a characteristic absorbance spectrum and will show one of the three primary colors when illuminated with white visible light-wavelength ranges from 380 nm to 780 nm. The controlled mixing of primary colors from each color filter unit produced by colorant will generate the final color of pixels. So the efficiency of color filter directly impacts the LCD's performance

Normally, the commercialized colorants used in a LCD color filter are pigments, because they have good stability against heat, light and chemicals. Unfortunately pigments must be ground into micro/nano particles before being added into a color resist to make a color filter due to their intrinsic insolubility property. When the color filter is illuminated, light scattering will take place on these particles with diameter of about 100 nm. As a result transmittance will become lowed, which means more light energy must be applied to provide enough brightness of the LCD.

In contrast to pigments, dyes are soluble in many materials which ensure that they can be dispersed at molecular level. If dyes are used in a color filter instead of pigments, light scattering will be significantly reduced. Thus it could be imagined that the dye based color filter will have higher transmittance and energy cost will thus be reduced greatly. However, dye's stability against light, heat and chemical resistance is generally inferior to pigments. As a result, at present, the commercialized LCD color filters contain pigments while a few LCD contain a hybrid (or combination) of pigment and dye.

Some phthalocyanine dyes are used for color filters of a LCD. Some phthalocyanine dyes has been proposed for color filters, see e.g. U.S. Pat. No. 5,968,688, US2011/0020738A, U.S. Pat. No. 6,238,827, U.S. Pat. No. 7,521,158, U.S. Pat. No. 7,713,342 and JP2012067229, but those dyes generally have insufficient thermal stability or insoluble common organic solvent for a color filter.

Inventors of this invention had developed a long alkyl/alkenyl aryloxy group substituted phthalocyanine compound with good thermal stability and high solubility in PGMEA as PCT/CN2013/080216.

Although the phthalocyanine structure is stable, it remains desirable to find a compound with improved affinity with resins commonly used in color filters to avoid a haze in the layer which could decrease transmittance. It also remains desirable to find a compound with improved solubility in solvents often used in manufacture of color filters for improved processability and shelf life.

### SUMMARY OF THE INVENTION

Therefore, inventors of this invention have further found that new type of phthalocyanine compound which shows affinity with resins used for a color filter as well as thermally stable and good solubility in a common organic solvent for a color filter.

Therefore, one aspect of the invention relates to an phthalocyanine compound represented by the formula (1).

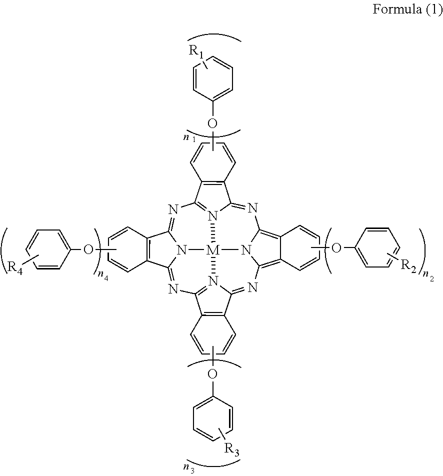

wherein R₁ to R₄ are selected from a saturated or unsaturated hydrocarbon group having 1 to 50 carbon atoms and an organic group containing one or more amine and 1 to 8 carbon atoms, n₁ to n₄ are integer from 1 to 4, M is a divalent ion, provided that (a) at least one of R₁ to R₄ is a saturated or unsaturated hydrocarbon group having 6 to 20 carbon atoms and (b) at least one of R₁ to R₄ is an organic group containing amine and 1 to 8 carbon atoms selected from a group (b-1) which contains an amide group characterized in that the nitrogen atom of the amide group is not a part of a heterocyclic group and a group (b-2) represented by the formula (2) —CH₂—X—NH₂(2), wherein X is selected from direct bond or divalent groups selected from the following formula (3)

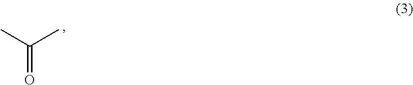

formula (4)

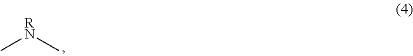

an alkylene group having 1 to 10 carbon atoms, an alkenylene group having 1 to 10 carbon atoms, and an arylene group, when one of R₁ to R₄ is the group (b-2), the rest of R₁ to R₄ are saturated or unsaturated hydrocarbon groups having 6 to 20 carbon atoms, and when two of R₁ to R₄ are the groups (b-1), the rest of R₁ to R₄ are saturated or unsaturated hydrocarbon groups having 6 to 20 carbon atoms.

One preferable aspect of this invention is the group (b-1) of the compound is represented by the formula (5)

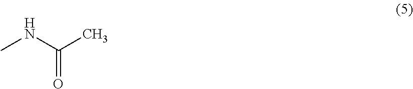

Another preferable aspect of this invention is X in the formula (2) of the group (b-2) is represented by the formula (3)

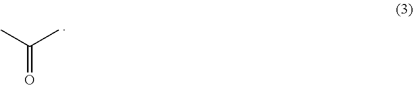

Other aspect of this invention relate to methods for synthesis the above preferable phthalocyanine compounds, the methods comprises the step of contacting a phthalonitrile compound (A) represented by the formula (6) with a phthalonitrile compound (B) represented by the formula (7) or a phthalonitrile compound (C) represented by the formula (8) under the presence of a metal salt.

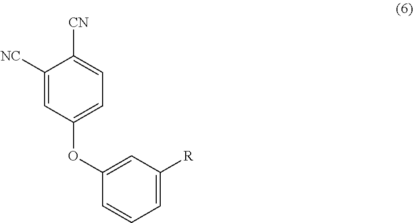

wherein R is selected from saturated or unsaturated hydrocarbon having 6 to 20 carbon atoms.

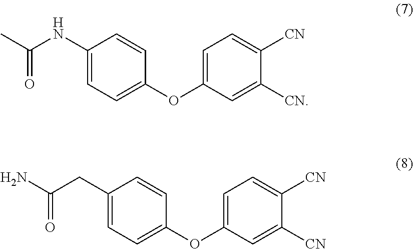 [SMILES: CC(=O)Nc1ccc(Oc2ccc(C#N)c(C#N)c2)cc1 ; N#Cc1ccc(Oc2ccc(CC(N)=O)cc2)cc1C#N]

Further aspects of this invention relate to a composition comprising the phthalocyanine compound and a resin; an article having a polymer layer formed from the composition and a color filter formed from the composition.

This group of phthalocyanine compounds have excellent thermal stability and enough solubility for an organic solvent used for a color filter. In addition, the phthalocyanine compounds show affinity with resins used for a color filter, so the phthalocyanine compositions of this invention are useful for a color filter used in a LCD.

### DETAILED DESCRIPTION OF THE INVENTION

As used throughout this specification, the abbreviations given below have the following meanings, unless the context clearly indicates otherwise: g=gram; mg=milligram; mm=millimeter; min.=minute(s); s=second(s); hr.=hour(s); rpm=revolution per minute; ° C.=degree Centigrade. Throughout this specification, “(meth)acrylic” is used to indicate that either “acrylic” or “methacrylic” functionality may be present. As used throughout this specification, the word ‘resin’ and ‘polymer’ is used interchangeably. The word ‘alkaline soluble resin’ and ‘binder’ is used interchangeably.

<Phthalocyanine Compound>

The present invention provides a phthalocyanine compound represented by the formula (1)

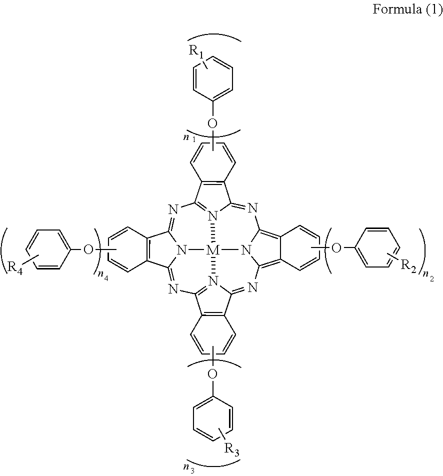

In the formula (1), R₁ to R₄ are selected from a saturated or unsaturated hydrocarbon group having 1 to 50 carbon atoms and an organic group containing one or more amine and 1 to 8 carbon atoms. n₁ to n₄ are integer from 1 to 4. M is a divalent ion, preferably a divalent metal cation. Examples of M include Zn²⁺, Cu²⁺, Ni²⁺, Co²⁺ and Mg²⁺.

The saturated or unsaturated hydrocarbon group having 1 to 50 carbon atoms above has at least 1 carbon atom, preferably at least 8 carbon atoms, and has less than 50 carbon atoms, preferably less than 20 carbon atoms. The hydrocarbon group includes straight-chain, branched or cyclic hydrocarbon groups. Unsaturated hydrocarbon includes alkene, alkadiene, alkapolyene such as alkatriene and alkatetraene, alkyne, alkadiyne, alkapolyyne such as alkatriyne and alkatetrayne, alkenyne and alkapolyenyne such as alkatrienyne and alkenediyne. Examples of the saturated hydrocarbon group include; methyl, ethyl, propyl, butyl, hexyl, octyl, decyl, dodecyl, hexadecyl, octadecyl, isopropyl, sec-propyl, sec-butyl, tert-butyl, 2-ethylhexyl, cyclohexyl, 1-norbornyl and 1-adamantyl. Examples of the unsaturated hydrocarbon groups include; hexa-3-enyl, hexa-2,4-dienyl, hexa-1-ynyl, hexa-1,3-diynyl, hexa-1-en-3-ynyl, pentadeca-8-enyl, pentadeca-8,11-dienyl, pentadeca-8,11,14-tryenyl, pentadeca-8-ynyl and pentadeca-8,11-diynyl.

The organic group containing amine and 1 to 8 carbon atoms in the formula (1) includes a group comprising amide group (amide segment) and a group comprising amino group (amino segment).

When one atomic bonding of the amine connects to a carbonyl, the obtained group has amide group. When two atomic bondings of the amine connect to two hydrogen atoms, the obtained group has amino group.

In the formula (1), (a) at least one of R₁ to R₄ is a saturated or unsaturated hydrocarbon group having 6 to 20 carbon atoms. The saturated or unsaturated hydrocarbon groups are same as the one disclosed above, but the number of carbon atoms is required from 6 to 20.

In the formula (1), (b) at least one of R₁ to R₄ is an organic group containing amine and 1 to 8 carbon atoms selected from the following two groups, group (b-1) and group (b-2).

Group (b-1) is a group which contains an amide group characterized in that the nitrogen atom of the amide group is not a part of a heterocyclic group. Examples of such group includes methyl amide group, ethyl amide group, propan amide group, butan amide group, pentan amide group, hexan amide group, heptan amide group and octan amide group. The nitrogen atom of the amide group is not a part of a heterocyclic group. As disclosed later, inventors of this invention found that the thermal stability is not high when a nitrogen atom of an amide group is a part of heterocyclic group like piperazine ring.

Group (b-2) is a group represented by the formula (2).

—CH₂—X—NH₂ (2)

In the formula (2), X is selected from direct bond or divalent groups selected from formula (3)

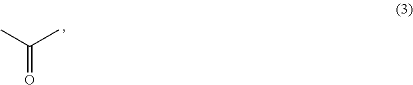

formula (4)

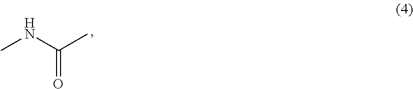

an alkylene group having 1 to 10 carbon atoms, an alkenylene group having 1 to 10 carbon atoms, and an arylene group.

When two of R₁ to R₄ are the groups (b-1), the rest of R₁ to R₄ are saturated or unsaturated hydrocarbon groups having 6 to 20 carbon atoms. Preferably, the amide group of the group (b-1) is disclosed in the formula (5).

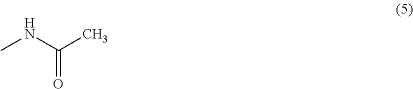

When one of R₁ to R₄ is the group (b-2), the rest of R₁ to R₄ are saturated or unsaturated hydrocarbon groups having 6 to 20 carbon atoms. Preferably, X of the group (2) is disclosed in the formula (3).

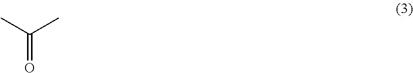

The phthalocyanine compound of the present invention can be used as a mixture of phthalocyanine compounds which have different substituents.

The phthalocyanine compound of the formula (1) is useful for a color filter of a LCD since the phthalocyanine compound of the invention has excellent thermal stability and high enough solubility for an organic solvent used for a color filter, as well as good affinity with a resin used for a color filter.

Other aspects of the invention are two methods for synthesis of the phthalocyanine compounds disclosed above.

The first method comprises the step of contacting a phthalonitrile compound (A) represented by the formula (6) with a phthalonitrile compound (B) represented by the formula (7) under the presence of a metal salt.

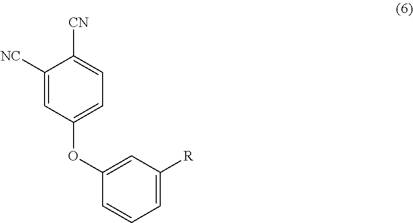

wherein R is selected from saturated or unsaturated hydrocarbon having 6 to 20 carbon atoms.

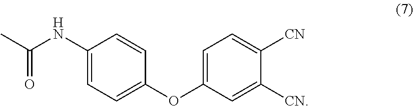 [SMILES: CC(=O)Nc1ccc(Oc2ccc(C#N)c(C#N)c2)cc1]

The mole ratio of the phthalonitrile compound (A) represented by the formula (6)/a phthalonitrile compound (B) represented by the formula (7) is from 0.01/100 to 100/0.01, preferably the mole ratio is from 10/1 to 1/10. More preferably, the mole ratio is from 1.5/1 to 0.7/1. The most preferably, the mole ratio is around 1.3/1.

The metal salt includes zink acetate (Zn(OAc)₂), copper acetate (Cu(OAc)₂), nickel acetate (Ni(OAc)₂), cobalt acetate (Co(OAc)₂), magnesium acetate (Mg(OAc)₂), copper chloride (CuCl₂), nickel chloride (NiCl₂), cobalt chloride (CoCl₂) and magnesium chloride (MgCl₂). The mole ratio of the amount of compound (A) and compound (B)/metal salt is basically from 1/10 to 10/1, preferably the mole ratio is from 3/1 to 5/1.

The reaction is normally conducted in a solvent. Preferably the solvent has a boiling point of 60° C. or higher. Examples of solvents used in the invention include alcohols such as 1-hexanol, methanol and ethanol, dimethyl formamide and butanol.

A catalyst can be used for the reaction. Preferable catalyst includes 1,8-Diazabicyclo[5.4.0]undec-7-ene (DBU), 1,5-Diazabicyclo[4.3.0]non-5-ene (DBN) and 4-Dimethylaminopyridine (DMAP). The amount of the catalyst is 0.5 to 10 times by the phthalonitrile compound (A).

The temperature and time of the reaction vary depending on the kind of solvent or other conditions, but it is from 70 to 200 for 24 to 36 hours.

The obtained phthalocyanine compound can be purified on silica gel chromatography or any other methods known in the art.

The second method comprises the step of contacting the phthalonitrile compound (A) with a phthalonitrile compound (C) represented by the formula (8) under the presence of a metal salt.

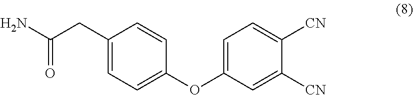 [SMILES: N#Cc1ccc(Oc2ccc(CC(N)=O)cc2)cc1C#N]

The mole ratio of the phthalonitrile compound (A) represented by the formula (6)/a phthalonitrile compound (C) represented by the formula (8) is from 0.01/100 to 100/0.01, preferably the mole ratio is from 10/1 to 1/10. More preferably, the mole ratio is from 2/1 to 5/1. The most preferably, the mole ratio is around 3/1.

The metal salt includes zink acetate (Zn(OAc)₂), copper acetate (Cu(OAc)₂), nickel acetate (Ni(OAc)₂), cobalt acetate (Co(OAc)₂), magnesium acetate (Mg(OAc)₂), copper chloride (CuCl₂), nickel chloride (NiCl₂), cobalt chloride (CoCl₂) and magnesium chloride (MgCl₂). The mole ratio of the amount of compound (A) and compound (C)/metal salt is basically from 1/10 to 10/1, preferably the mole ratio is from 3/1 to 5/1.

The reaction is normally conducted in a solvent. Preferable solvent has 60° C. or higher boiling point. Examples of solvents used in the invention include alcohols such as 1-hexanol, methanol and ethanol, dimethyl formamide and butanol.

A catalyst can be used for the reaction. Preferable catalyst includes 1,8-Diazabicyclo[5.4.0]undec-7-ene (DBU), 1,5-Diazabicyclo[4.3.0]non-5-ene (DBN) and 4-Dimethylaminopyridine (DMAP). The amount of the catalyst is 0.5 to 10 times by the phthalonitrile compound (A).

The temperature and time of the reaction vary depending on the kind of solvent or other conditions, but it is from 70 to 200 for 24 to 36 hours.

The obtained phthalocyanine compound can be purified on silica gel chromatography, recrystallization or any other methods known in the art.

<Composition>

The composition of the present invention comprises at least one compound as recited in formula (1) and a resin. The resin is preferably alkaline soluble resin. The composition preferably additionally comprises a cross-linker (cross-linking agent), a solvent and a radiation-sensitive compound such as a photo initiator. The composition of the present invention can be a negative type photosensitive composition. The word “negative type” means a property that the exposed parts become insoluble to developer. The composition can form a film useful for a color filter.

The content of the compound as recited in formula (1) in the composition of the present invention varies depending on each molar absorption coefficient and required spectral characteristics, film thickness, or the like, but it is preferably at least 1 wt %, more preferably at least 2 wt %, the most preferably at least 5 wt % based on the total solid contents of the composition. The preferable content is less than 80 wt %, more preferably less than 70 wt %, the most preferably less than 50 wt % based on the total solid contents of the composition.

The composition of the present invention can comprises other coloring materials (colorants) in addition to the composition as recited in formula (1). Normally the use of additional coloring material is determined from the required spectral characteristics of a material to be formed from the composition. Any known dyes or pigments can be used.

The alkaline soluble resin is also known as ‘binder’ in this technical art. Preferably, the alkaline soluble resin is dissolved in an organic solvent. The alkaline soluble resin can be developed with an alkaline solution such as tetramethyl ammonium hydroxide aqueous solution (TMAH) after forming a film.

The alkaline soluble resin (binder) is normally a linear organic polymer. The binder optionally has a crosslinkable group within the polymer structure. When the composition of the present invention is used as a negative type photosensitive composition, such crosslinkable group can react and form crosslink by exposure or heating so that the binder becomes a polymer which is insoluble to a developer such as an alkaline.

Many kinds of binder are known in this art. Examples of such binder are; (meth)acrylic resin, acrylamide resin, styrenic resin, polyepoxyde, polysiloxane resin, phenolic resin, novolak resin, and co-polymer or mixture of those resins. In this application, (meth)acrylic resin (polymer) includes copolymer of (meth)acrylic acid or ester thereof and one or more of other polymerizable monomers. For example, acrylic resin can be polymerized from acrylic acid and/or acrylic ester and any other polymerizable monomers such as styrene, substituted styrene, maleic acid or glycidyl (meth)acrylate.

In those binder, a resin comprising (meth)acrylic resin (polymer) is preferable for the composition. Because such resin has affinity with the phthalocyanine compound of this invention, so the shelf time of the composition is long, as well as an obtained color filter has clear morphology.

The binder preferably has at least 1,000 of weight-average molecular weight (Mw), more preferably at least 2,000 of Mw, the most preferably at least 10,000 of Mw measured by a GPC method using polystyrene as a standard. At the same time, the binder preferably has less than 200,000 of Mw, more preferably less than 100,000 of Mw measured by the same method described above.

The amount of the binder used in the composition of the present invention is preferably at least 10 wt %, more preferably at least 20 wt % based on the total solid contents of the composition. At the same time, the preferable amount of the binder is less than 90 wt %, more preferably less than 80 wt % based on the total solid contents of the composition.

The composition of this invention optionally further comprises a cross-linking agent to obtain a further hardened material. When the composition of this invention is used as a negative type photosensitive composition, such cross-linking agent can form a crosslink by exposure or heating and contribute to get a further hardened material. Well known cross-linking agent can be used for the composition of this invention. Examples of cross-linking agents are epoxy resin and substituted nitrogen containing compound such as melamine, urea, guanamine or glycol uril.

The composition of this invention optionally further comprises a solvent. The solvent to be used for the composition is not limited, but preferably selected from the solubility of components of the composition such as alkaline soluble resin or phthalocyanine dye. Examples of the preferable solvent include esters such as ethylacetate, n-butyl acetate, amyl formate, butyl propionate or 3-ethoxypropionate, ethers such as diethylene glycol dimethyl ether, ethylene glycol monomethyl ether or propylene glycol ethyl ether acetate and ketones such as methylethylketone, cyclohexanone or 2-heptanone.

When the composition of this invention is a negative type radiation-sensitive composition, the composition preferably comprises a photo initiator. Photo initiator also called as photopolymerization initiator and including radical initiator, cationic initiator and anionic initiator. Examples of a photo initiator include; oxime esther type initiator, sulfonium salts initiator, iodide salts initiator and sulfonate initiator.

The composition of this invention can comprise other radiation-sensitive compound such as a radiation sensitive resin or a photo acid generator.

<Polymer Layer>

The composition of the present invention described above can form a polymer layer on an article. The polymer layer also described as ‘polymer film’ in the specification.

The contents of the compound as recited in formula (1) in the polymer layer is depend on the required color of the film, and it is basically the same as the content of the compound as recited in formula (1) in the composition. The polymer layer also comprises an alkaline soluble resin which is disclosed above.

The polymer layer optionally comprises a photo initiator, a photo acid generator, a radiation sensitive resin and a crosslink agent disclosed above.

The method of forming the polymer layer on an article comprises the steps of; mixing the compound as recited in formula (1) with an alkaline soluble resin and solvent, coating the mixture on an article which supports a layer and heating the article to form a polymer layer (film). Optionally, the method comprises one or more of steps of exposing a layer (film) or curing a layer to form crosslinked stable layer.

The alkaline soluble resin and the solvent used to the method for forming the polymer layer are same as the one disclosed above.

Examples of an article which supports a layer (film) are glass, metal, silicon substrate and metal oxide coated material.

Any coating method can be used for the coating step, such as rotation coating, cast coating or roll coating.

The thickness of the layer (film) varies depending on the required properties of the film. The thickness of the layer is 0.1 to 4 micron, preferably 0.5 to 3 micron.

The layer (film) has high transmittance and thermal stability from the properties of the phthalocyanine composition of this invention. The phthalocyanine composition can be dissolved in an organic solvent, and has high thermal stability. Therefore the composition does not prevent the transmittance of a film and does not decrease the thermal stability of the film. Such property is important for a color filter of LCD. Therefore, the layer (film) of the present invention is useful as a color filter of LCD.

<Color Filter>

The color filer of this invention is formed from the composition comprising at least one compound as recited in formula (1) and a resin. The layer (film) disclosed above can be used for the color filter. Normally, a color filter has multiple units which made from colored films comprising Red/Green/Blue colorants.

The contents of the compound as recited in formula (1) in a colored film for a color filter is basically the same as the content in the film disclosed above.

A film used for a color filter can be formed by the following steps; coating a solution comprising the compound as recited in formula (1), binder, a photo initiator and solvent to form a radiation sensitive composition layer on a material, exposing the layer through a patterned mask, and developing the layer with an alkaline solution. Moreover, a curing step of further heating and/or exposing the layer after developing step may be conducted as needed.

Since a color filter comprises three colored films which comprise R/G/B colorant, the steps of forming each colored film are repeated, then a color filter having such three colored films are obtained.

### EXAMPLES

### Inventive Example 1 and Comparative Examples 1-3

A phthalocyanine compound (Compound I) disclosed below was used in Inventive Example 1, and the three phthalocyanine compounds (Compounds II-IV) disclosed below were used in Comparative Examples 1-3.

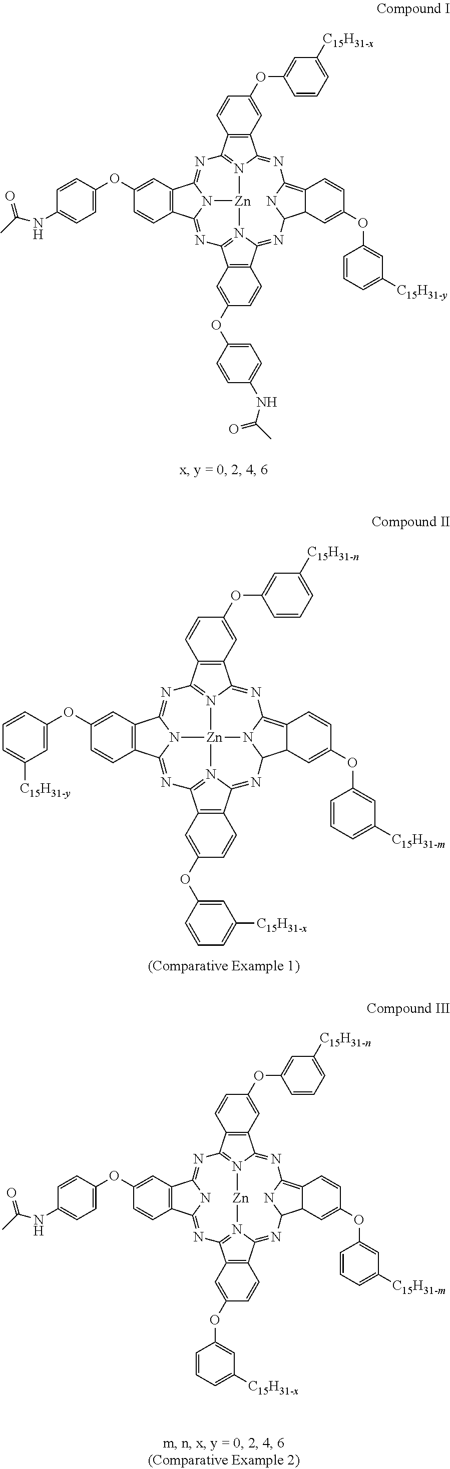

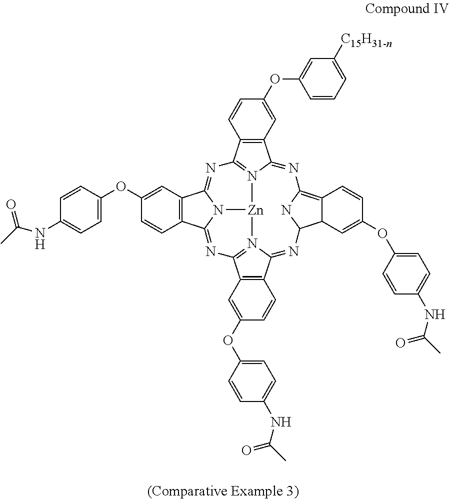

### a. Synthesis of Phthalonitrile (A-1)

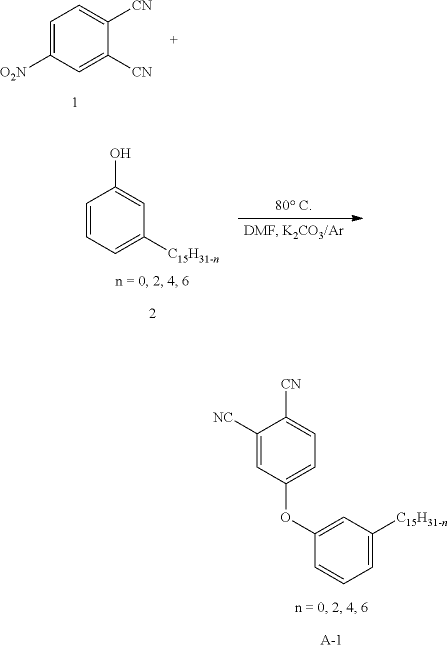

1 g of 4-nitrophthalonitrile (5.77 mmol) and 2.7 g of the above compound 2 (6.3 mmol) were dissolved in 30 ml of dry N,N-dimethylformamide (DMF), then 1.2 g of anhydrous K₂CO₃ (8.7 mmol) was added in portions during 4 h. The mixture was stirred at 80° C. for 10 h under nitrogen atmosphere. After that, the solvent was removed, the residue was purified on silica gel chromatography to get oily liquid phthalonitrile (A-1) (2.2 g, yield: 90%). ¹H NMR (CDCl₃, ppm): 7.70 (d, J=10Hz 1H), 7.40-7.11 (m, 4H), 6.90-6.86 (m, 2H), 5.40-5.30 (m, OH-6H), 2.82-0.86 (m, 19H-31H). LC-MS: n=6, m/z (M+NH₄)⁺, 442.2847; n=4, m/z (M+NH₄)⁺, 444.3008; n=2, m/z (M+NH₄)⁺, 446.3157.

### b. Synthesis of Phthalonitrile (B-1)

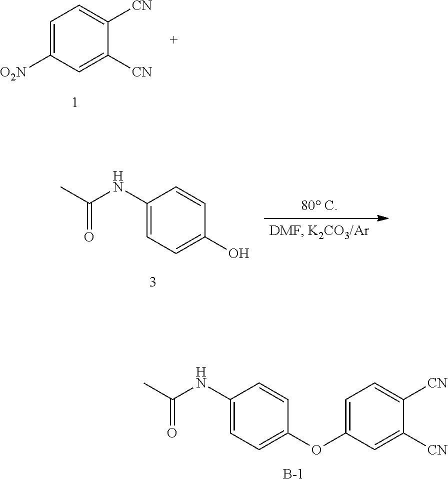

5 g of 4-nitrophthalonitrile (28.9 mmol) and 5.67 g of the above compound 3 (37.8 mmol) were dissolved in 50 ml of dry DMF, then 5.9 g of anhydrous K₂CO₃ (43.1 mmol) was added in portions during 4 h. The mixture was stirred at 80° C. for 10 h under nitrogen atmosphere. After that, the mixture was poured into 3 L water, filtered and dried to get white powder (7.6 g, 95%). ¹H NMR (d-DMSO, ppm): 10.10 (s, 1H), 8.07 (d, 1H), 7.74 (d, 1H), 7.68 (d, 2H), 7.33 (m, 1H), 7.13 (d, 2H), 2.06 (s, 3H). LC-MS: m/z (M+H)⁺, 278.0936.

### c. Synthesis of Compounds I-IV for Inventive Example 1 and Comparative Examples 1-3

A mixture of 2 g of phthalonitrile B-1 (7.2 mmol) and 4.0 g of phthalonitrile A-1 (9.36 mmol) and 0.76 g of Zn(OAc)₂ (4.1 mmol) in 80 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound I). (0.93 g, yield: 15.2%). LC-MS: (M⁺ or M+H⁺) 1470.6172, 1471.6262, 1473.6375, 1474.6440, 1475.6495.

During the synthesis of Compound I, Compounds II-IV were also obtained and purified on silica gel chromatography.

The yield and analytical data for compounds II-IV are disclosed below.

Compound II (Comparative example 1): yield: 0.58 g (8%). LC-MS: (M⁺ or M+H⁺) 1764.9571, 1766.9640, 1768.9806, 1769.9852, 1771.9945, 1774.0088, 1775.0180, 1777.0254.

Compound III (Comparative example 2): yield: 0.74 g (11%). LC-MS: (M⁺ or M+H⁺) 1616.7869, 1617.9722, 1618.7969, 1619.8030, 1620.8071, 1621.8110, 1622.8166, 1623.8173.

Compound IV (Comparative example 3): yield:0.22 g (4%). LC-MS: (M⁺ or M+H⁺) 1324.4598.

### d. Preparation of a Color Resist and a Color Film Comprising Phthalocyanine Compounds

10 g of alkaline soluble acrylic resin solution (MIPHOTO RPR4022, supplied from Miwan Commercial Co., Ltd., 40 wt % of solid content in methyl 3-methoxypropionate) was mixed with 1.5 g of PGMEA ((10)wt %). 1.14 g of Compound I was mixed in the alkaline soluble resin/PGMEA solution and shaked for 5 hours at room temperature. The solution was filtered through a 0.45 μm PTFE filter to remove large particles. Then the filtered solution was spin coated onto a clean glass substrate with 400 rpm spin speed for 18 seconds. The obtained film was first dried at 90° C. under air atmosphere for 1.5 hour, and then at 180° C. for 30 minutes to remove the solvent. The obtained dry film was baked at 230° C. under air atmosphere for 1 hour, then further hard baked at 230° C. under air atmosphere for 1 hour to check the thermal stability. The CIE values (xyY values and lab values) and the transmittance were measured before and after the hard bake.

Same procedure was conducted for Compound II-XI of Inventive Examples 2-3 and Comparative Examples 1-8.

### Inventive Example 2

A phthalocyanine compound (Compound V) disclosed below was used in Inventive Example 2.

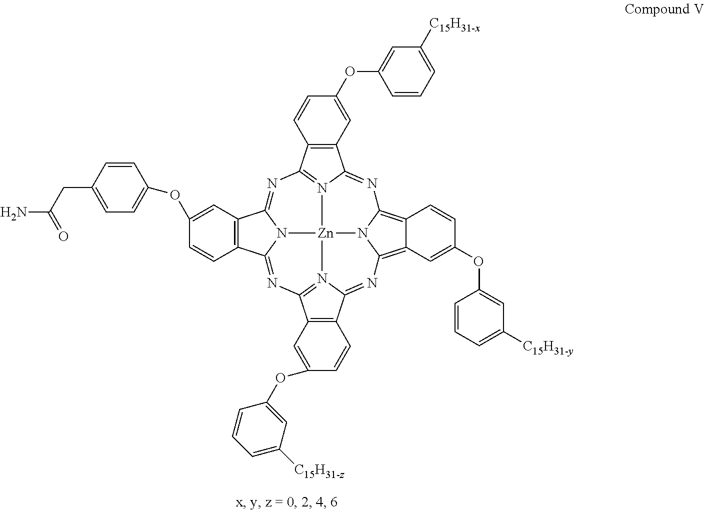

### a. Synthesis of Phthalonitrile Compound (C-1)

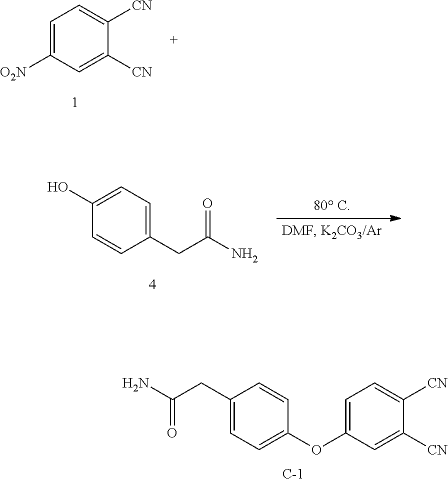

5 g of 4-nitrophthalonitrile (28.9 mmol) and 4.8 g of compound 4 (31.5 mmol) were dissolved in 50 ml of dry DMF, then 5.9 g of anhydrous K₂CO₃ (43.1 mmol) was added in portions during 4 h. The mixture was stirred at 80° C. for 10 h under nitrogen atmosphere. After that, the mixture was poured into 3 L water, filtered and dried to get white powder (6.8 g, 85%). ¹H NMR (d-DMSO, ppm): 8.07 (d, 1H), 7.77 (d, 1H), 7.47 (s, 1H), 7.34 (m, 3H), 7.12 (d, 2H), 6.93 (s, 1H), 3.42 (s, 2H). LC-MS: m/z (M+H)⁺ 278.0945

### b. Synthesis of Compound V

A mixture of 1 g of phthalonitrile C-1 (3.6 mmol), 4.6 g of phthalonitrile A-1 (10.1 mmol) and 0.63 g of zinc acetate (Zn(OAc)₂) (3.4 mmol) in 50 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound V). (1.7 g, yield: 29%). LC-MS: m/z (M or M+H)⁺ 1615.7796, 1617.7862, 1618.7986, 1620.8078, 1622.8229, 1624.8346, 1625.8383, 1627.8509, 1629.8616, 1631.8645.

Prepared color resists and color films same as Inventive Example 1. The chromaticity coordinates are shown below.

| | Spin-coating | | | |
|---|---|---|---|---|
| | rate | Y | x | y |
| Compound V | 350 rpm | 64.32 | 0.2399 | 0.3294 |
| (5 wt %) | 250 rpm | 57.47 | 0.22 | 0.3279 |
| | 150 rpm | 43.28 | 0.1817 | 0.3251 |

### Inventive Example 3

A phthalocyanine compound (Compound VI) disclosed below was used in Inventive Example 3.

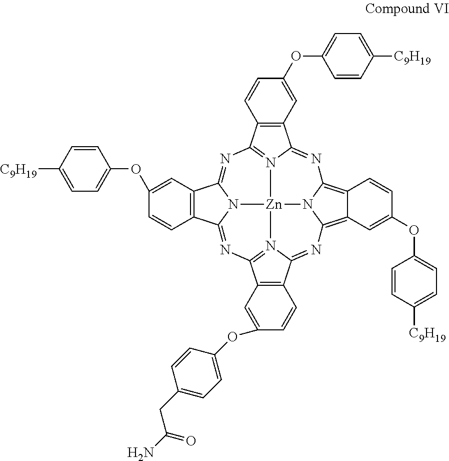

### a. Synthesis of Phthalonitrile (A-2)

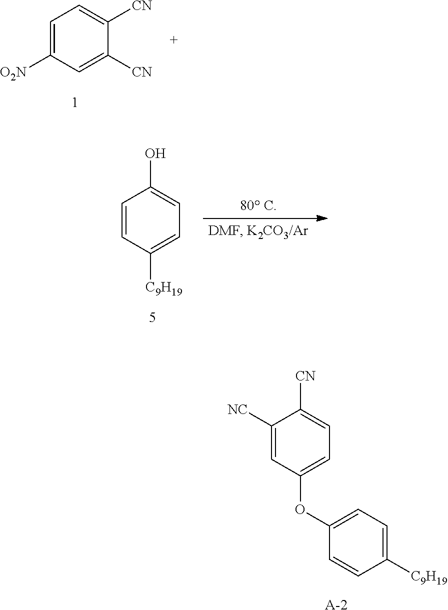

5 g of 4-nitrophthalonitrile (28.9 mmol) and 8.3 g of 5 (37.8 mmol) were dissolved in the 50 ml of dry DMF, and 5.9 g of anhydrous K₂CO₃ (43.1 mmol) was added in portions during 4 hours. The mixture was stirred at 80° C. for 10 hours under the nitrogen atmosphere. Then the solvent was removed, and the residue was purified on silica gel chromatography to get oily liquid phthalonitrile A-2 (8.5 g, yield: 85%). LC-MS: m/z (M+NH₄)⁺ 364.2187.

### b. Synthesis of Compound VI

A mixture of 0.8 g of phthalonitrile C-1 (2.9 mmol), 3 g of phthalonitrile A-2 (8.6 mmol) and 0.53 g of Zn(OAc)₂ (2.9 mmol) in 50 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound VI). (1.3 g, yield: 32.5%). LC-MS: m/z (M or M+H)⁺ 1380.6362.

### Comparative Example 4

A phthalocyanine compound (Compound VII) disclosed below was used in Comparative Example 4.

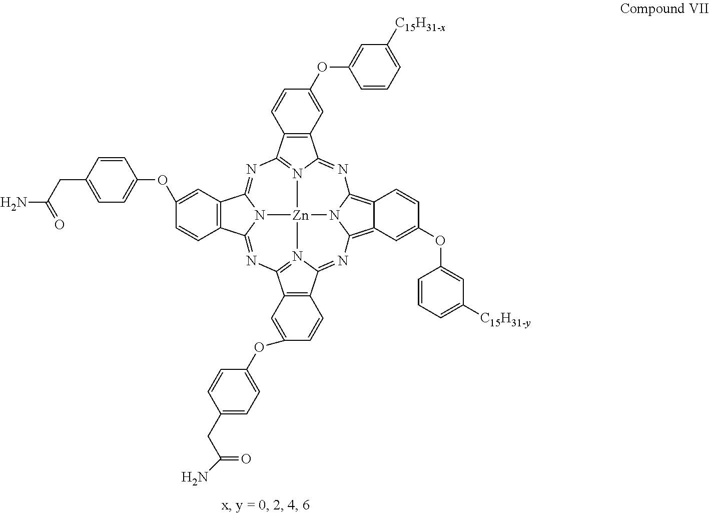

### a. Synthesis of Compound VII

A mixture of 1.6 g of phthalonitrile C-1 (5.8 mmol), 3.2 g of phthalonitrile A-1 (7.5 mmol) and 0.61 g of Zn(OAc)₂ (3.3 mmol) in 80 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound VII). (0.64 g, yield: 14.9%). LC-MS: m/z (M or M+H)⁺ 1470.6158, 1471.6254, 1473.6357, 1475.6499, 1477.6595.

### Comparative Example 5

A phthalocyanine compound (Compound VIII) disclosed below was used in Comparative Example 5.

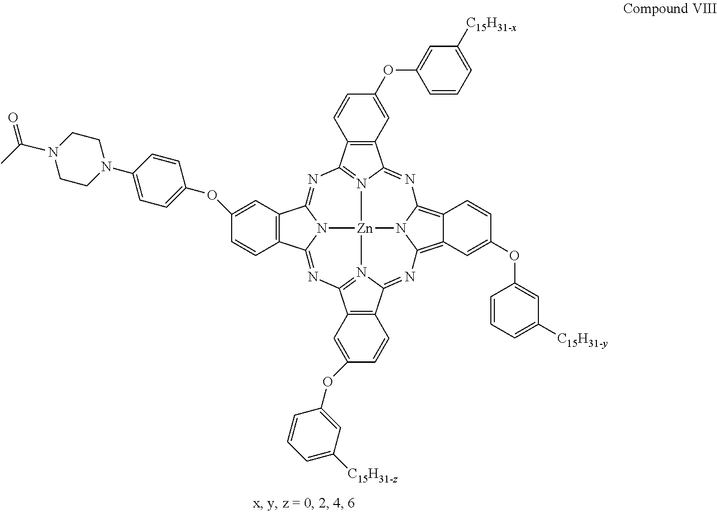

### a. Synthesis of Phthalonitrile Compound (C-2)

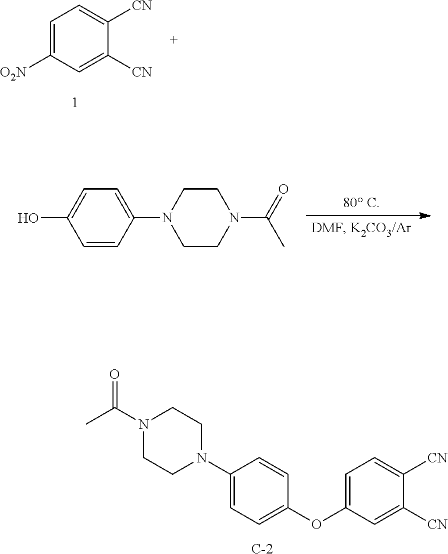

5 g of 4-nitrophthalonitrile (28.9 mmol) and 8.3 g of 6 (37.8 mmol) were dissolved in 50 ml of dry DMF, and 5.9 g of anhydrous K₂CO₃ (43.1 mmol) was added in portions during 4 hours. The mixture was stirred at 80° C. for 10 hours under the nitrogen atmosphere. Then the mixture was poured into 3 L water, filtered and dried to get slightly gray powder (9.5 g, yield: 95%). ¹H NMR (d-DMSO, ppm): 8.05 (d, 1H), 7.69 (d, 1H), 7.29 (dd, 1H), 7.07 (m, 4H), 3.59 (m, 4H), 3.10 (m, 4H), 2.05 (s, 3H). LC-MS: m/z (M+H)⁺ 347.1503.

### b. Synthesis of Compound VIII

A mixture of 2 g of phthalonitrile C-2 (5.8 mmol), 3.2 g of phthalonitrile A-1 (7.5 mmol) and 0.61 g of Zn(OAc)₂ (3.3 mmol) in 80 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound VIII). (1.47 g, yield: 14.9%). LC-MS: m/z (M or M+H)⁺ 1685.8464,1687.8613, 1689.8713, 1690.8763, 1691.8838, 1692.8869, 1694.9026, 1696.9121, 1697.9175, 1698.9265.

### Comparative Example 6

A phthalocyanine compound (Compound IX) disclosed below was used in Comparative Example 6.

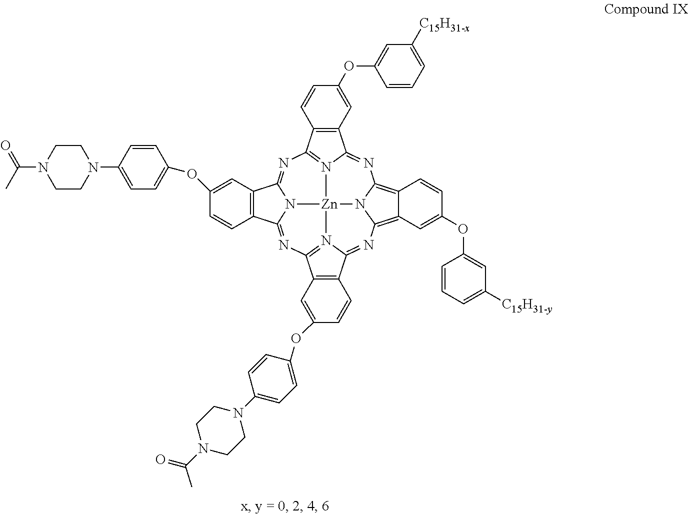

### a. Synthesis of Compound IX

A mixture of 2 g of phthalonitrile C-2 (5.8 mmol), 3.2 g of phthalonitrile A-1 (7.5 mmol) and 0.61 g of Zn(OAc)₂ (3.3 mmol) in 80 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound IX). (0.9 g, yield: 19.2%). LC-MS: m/z (M or M+H)⁺ 1606.7336, 1607.7382, 1609.7504, 1611.7602, 1613.7715, 1614.7781, 1615.7823, 1616.7853, 1617.7890, 1618.7933.

### Comparative Example 7

A phthalocyanine compound (Compound X) disclosed below was used in Comparative Example 7.

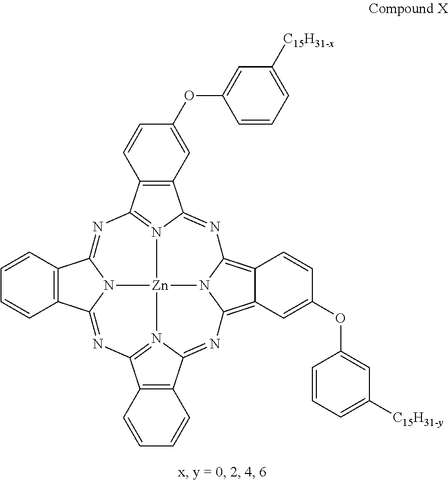

### a. Synthesis of Compound X

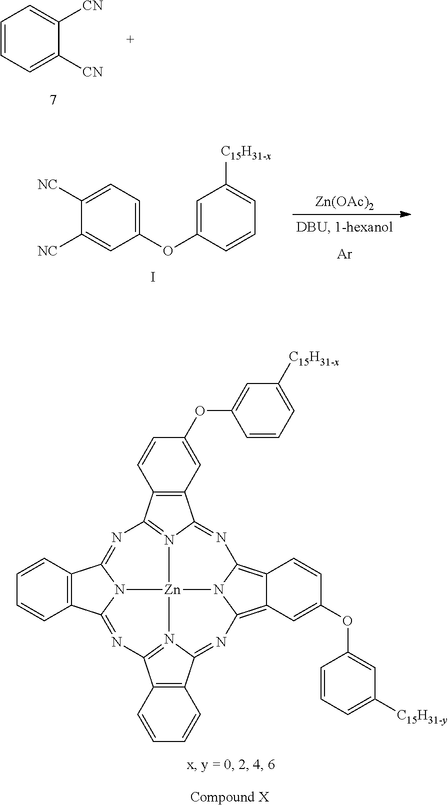

A mixture of 0.96 g of phthalonitrile 7 (7.5 mmol), 3.2 g of phthalonitrile A-1 (7.5 mmol) and 0.68 g of Zn(OAc)₂ (3.7 mmol) in 80 mL of dry 1-hexanol was heated to 100° C., then 6 mL of DBU was added. The mixture was stirred at 140-150° C. for 24 h. And then the solvent was removed, the residue was purified on silica gel chromatography to get bluish solid compound (Compound X). (1.2 g, yield: 27.2%). LC-MS: m/z (M or M+H)⁺ 1169.5136, 1171.5221, 1173.5382, 1174.5418, 1175.5472, 1176.5504, 1177.5594, 1178.5638, 1180.5731.

### Comparative Example 8

A phthalocyanine compound (Compound XI) disclosed below was used in Comparative Example 8.

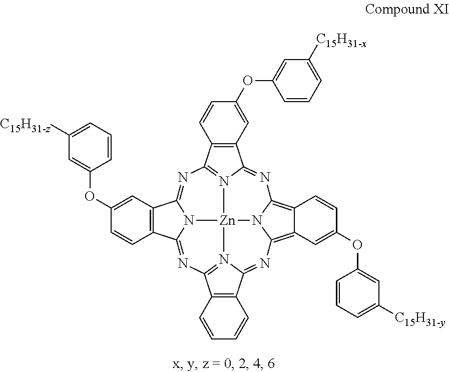

### a. Synthesis of Compound XI

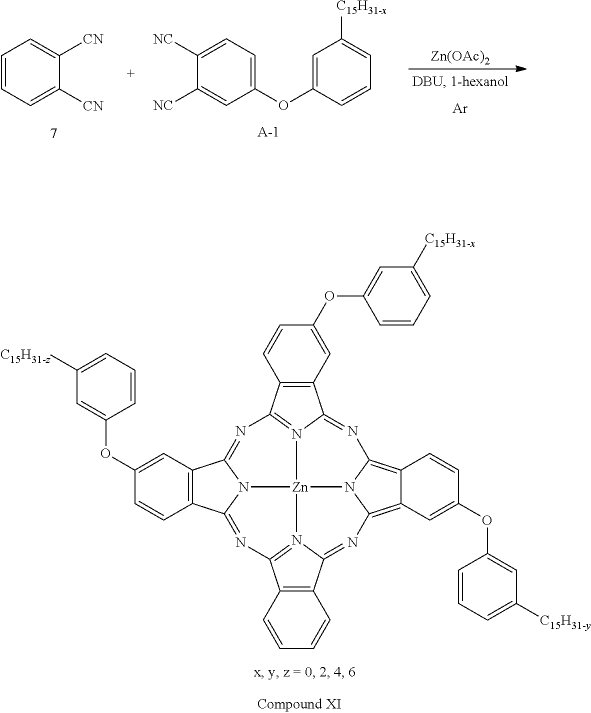

A mixture of 0.96 g of phthalonitrile 6 (7.5 mmol), 3.2 g of phthalonitrile A-1 (7.5 mmol) and 0.68 g of Zn(OAc)₂ (3.7 mmol) in 80 mL of dry 1-hexanol was heated to 100° C., then 6 mL of DBU was added. The mixture was stirred at 140-150° C. for 24 h. And then the solvent was removed, the residue was purified on silica gel chromatography to get greenish solid compound (Compound XI). (0.18 g, yield: 1.6%). LC-MS: m/z (M or M+H)⁺ 1470.7585, 1471.7659, 1472.7707, 1473.7801, 1474.7852, 1475.7828, 1476.7947, 1478.8077, 1479.8131, 1480.8183.

<Performance Evaluation>

(1) Thermal stability of compounds (Mass loss measured by TGA):
The thermal stability of compound itself was determined by the mass loss of compound measured by TGA under air atmosphere at 230° C. for 1 hour.

(2) Film Thickness:
Film thickness is measured by scanning the difference in height across the boundary of film and glass substrate with atomic force microscope.

(3) Chromaticity Coordinates:
The chromaticity coordinate of film on a glass sheet is directly recorded with UltraScan Pro (Hunterlab) colorimeter. The light source is D65/10.

(4) Thermal Stability of Films (Chromaticity):
The chromaticity coordinates (L, a, b) are recorded with UltraScan Pro (Hunterlab) colorimeter before and after the film is hard baked at target temperature (230° C.) for 1 hour. The thermal stability of a film is indicated by the difference of chromaticity coordinate before and after hard baking represented by the following formula;

ΔE=\sqrt{(L−L′)²+(a−a′)²+(b−b′)²}

TABLE 1

| | | | Solubility in | Thermal stability baked at 230° C. (ΔE) | | | | | Synthesis |
|---|---|---|---|---|---|---|---|---|---|
| Example No. and | | Compatibility | PGMEA | 0-30 | 30-60 | 60-90 | 0-60 | 0-90 | Yield |
| Compounds | | issue | (wt %) | min | min | min | min | min | % |
| Inv. Ex. 1 | I | No | 13 | — | — | — | 18.5 | 1.6 | 15.2 |
| | | | | | | | (1^{st} 1 hr) | (2^{nd} 1 hr) | |
| Inv. Ex. 2 | V | No | 18.7 | 3.0 | 2.9 | 0.9 | 3.0 | 3.8 | 29 |
| Inv. Ex. 3 | VI | No | 7.8 | 1.7 | 0.5 | 0.5 | 1.2 | 0.9 | 32.5 |
| Com. Ex. 1 | II | Yes | 18 | — | — | — | 3.0 | — | 45 |
| Com. Ex. 2 | III | Yes | 16 | — | — | — | 3.1 | — | 11 |
| Com. Ex. 3 | IV | No | 0.3 | — | — | — | — | — | 4 |
| Com. Ex. 4 | VII | No | 0.6 | — | — | — | — | — | 14.9 |
| Com. Ex. 5 | VIII | No | 15.5 | 11.5 | 3.2 | 4.0 | 14.1 | 15.8 | 14.9 |
| Com. Ex. 6 | IX | No | 4.8 | — | — | — | — | — | 19.2 |
| Com. Ex. 7 | X | Yes | 9.2 | 1.9 | 0.5 | 0.9 | 1.9 | 2.2 | 27.2 |
| Com. Ex. 8 | XI | Yes | 14.9 | 2.4 | 5.5 | 2.2 | 6.8 | 6.1 | 1.6 |

Although Comparative Examples 1, 2, 7 and 8 show high solubility in PGMEA and high thermal stability (ΔE was 3 or smaller after 1 hour 230° C. baking), the compatibility issues were observed. It resulted in the low transmittance of the film. Comparative Examples 3, 4 and 6 show insufficient solubility for PGMEA, which resulted by over many amide/amino groups. Comparative Example 5 shows poor thermal stability. Comparing to those Comparative Examples, Inventive Examples 1 to 3 show high solubility in PGMEA and high thermal stability, as well as no compatibility issues. It means that Compounds I, V and VI have an affinity with a resin, and good film forming performance. Moreover, all the inventive Examples have high synthesis yields, so that those have an advantage for industrial use.

### Inventive Examples 4-5

Mixtures of Compound V and commercial available dye were tested to obtain required color.

Inventive Example 4 (Compound V 5 wt %+solvent yellow 16 2 wt %)

10 g of alkaline soluble acrylic resin solution was mixed with 1.5 g of PGMEA. 0.62 g of Compound V and 0.25 g of solvent yellow 16 (CAS; 4314-14-1, Suzhou Sunway Dyes & Chemicals Co., Ltd.) were mixed in the alkaline soluble resin/PGMEA solution, the solution was filtered through a 0.45 μm PTFE filter to remove large particles. Then the filtered solution was spin coated onto a clean glass substrate for 18 seconds. The obtained films were dried at 90° C. under air atmosphere for 20min The color properties were tested.

### Inventive Example 5

### Compound V 5.1 wt %+Solvent Yellow 16 2.5 wt %

10 g of alkaline soluble acrylic resin solution was mixed with 1.5 g of PGMEA. 0.64 g of Compound V and 0.31 g of solvent yellow 16 (CAS; 4314-14-1, Suzhou Sunway Dyes & Chemicals Co., Ltd.) were mixed in the alkaline soluble resin/PGMEA solution, the solution was filtered through a 0.45 μm PTFE filter to remove large particles. Then the filtered solution was spin coated onto a clean glass substrate for 18 seconds. The obtained films were dried at 90° C. under air atmosphere for 20min The color properties were tested.

| | Spin-coating rate | Y | x | y |
|---|---|---|---|---|
| Inv. Ex. 4 | 150 rpm | 22.31 | 0.2316 | 0.6439 |
| | 250 rpm | 50.17 | 0.282 | 0.5101 |
| | 350 rpm | 58.41 | 0.2944 | 0.4698 |
| Inv. Ex. 5 | 150 rpm | 38.95 | 0.2909 | 0.5868 |
| | 250 rpm | 48.63 | 0.3087 | 0.5508 |
| | 350 rpm | 55.68 | 0.3175 | 0.5173 |

What is claimed is:

1. A phthalocyanine compound represented by the formula (1) 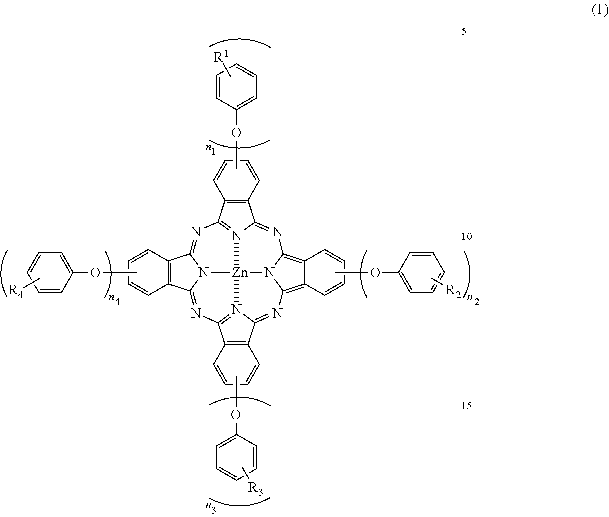
wherein R1 to R4 are selected from a saturated or unsaturated hydrocarbon group having 1 to 50 carbon atoms and an organic group containing amine and 1 to 8 carbon atoms, n1 to n4 are integer from 1 to 4, M is a divalent ion,
provided that (a) at least one of R1 to R4 is a saturated or unsaturated hydrocarbon group having 6 to 20 carbon atoms and
(b) at least one of R1 to R4 is an organic group containing amine and 1 to 8 carbon atoms selected from
a group (b-1) which contains an amide group characterized in that the nitrogen atom of the amide group is not a part of a heterocyclic group and
a group (b-2) represented by the formula (2)
—CH₂—X—NH₂ (2)
wherein X is selected from direct bond or divalent groups selected from formula (3) 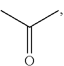
formula (4) 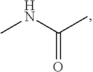
an alkylene group having 1 to 10 carbon atoms, an alkenylene group having 1 to 10 carbon atoms, and an arylene group,
when one of R1 to R4 is the group (b-2), the rest of R1 to R4 are saturated or unsaturated hydrocarbon groups having 6 to 20 carbon atoms, and
when two of R1 to R4 are the groups (b-1), the rest of R1 to R4 are saturated or unsaturated hydrocarbon groups having 6 to 20 carbon atoms.

2. The phthalocyanine compound of claim 1, wherein the group (b-1) is represented by the formula (5)

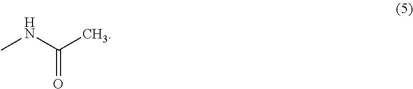

3. A method for synthesis the phthalocyanine compound of claim 2, comprising the step of contacting a phthalonitrile compound (A) represented by the formula (6) 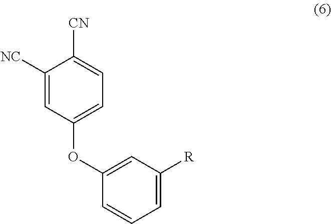
wherein R is selected from saturated or unsaturated hydrocarbon having 6 to 20 carbon atoms, with a phthalonitrile compound (B) represented by the formula (7) 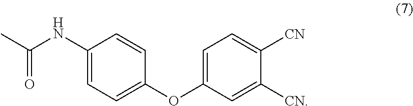 [SMILES: CC(=O)Nc1ccc(Oc2ccc(C#N)c(C#N)c2)cc1]
under the presence of a metal salt.

4. The method of claim 3, wherein the mole ratio of the phthalonitrile compound (A)/the phthalonitrile compound (B) is from 1.5/1 to 0.7/1.

5. The phthalocyanine compound of claim 1, wherein X of the formula (2) in the group (b-2) is

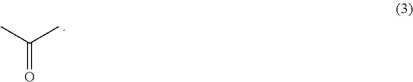

6. A method for synthesis the phthalocyanine compound of claim 5, comprising the step of contacting the phthalonitrile compound (A) with a phthalonitrile compound (C) represented by the formula (8) 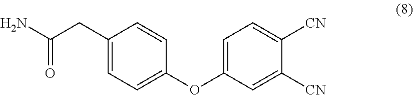 [SMILES: N#Cc1ccc(Oc2ccc(CC(N)=O)cc2)cc1C#N]
under the presence of a metal salt.

7. The method of claim 6, wherein the mole ratio of the phthalonitrile compound (A)/phthalonitrile compound (C) is from 2/1 to 5/1.

8. A composition comprising the phthalocyanine compound any of claims 1 to 2 and 5 and a resin.

9. The composition of claim 8, wherein the resin comprises methacrylic acid.

10. The composition of claim 8 or 9, further comprises another colorant.

11. The composition of any of claims 8 to 10, further comprising a radiation-sensitive compound.

12. An article having a polymer layer formed from the composition of any of claims 8 to 11.

13. The article of claim 12, wherein the polymer layer is a negative-type layer.

14. A color filter formed from the composition of any of claims 8 to 11.
